(19) United States
(12) Patent Application Publication
(10) Pub. No.: US 2004/0061545 A1
(43) Pub. Date: Apr. 1, 2004

(54) Timing generator with low delay multiplexer

(76) Inventor: Cosmin Iorga, Oak Park, CA (US)

Correspondence Address: Legal Department, Teradyne, Inc., 321 Harrison Avenue, Boston, MA, 02118, US

(21) Appl. No.: 10/259,334

(22) Filed: Sep. 27, 2002

(51) Int. Cl. H03K 17/62

(52) U.S. Cl. 327/408

(57) ABSTRACT

A timing generator for use in a semiconductor tester is disclosed. The timing generator includes a delay line having a plurality of delay elements with respective phase-shifted outputs and a multiplexer. The multiplexer includes a plurality of inputs for receiving the phase shifted outputs, and an output. The multiplexer further includes a plurality of switch circuits corresponding to the input circuits and disposed between each input circuit and the output to selectively isolate each input circuit from the output. The timing generator also includes phase detection circuitry for detecting the phase shift between the multiplexer output and a reference signal.

### FIELD OF THE INVENTION

The invention relates generally to automatic test equipment, and more particularly timing generation circuits for automatic test equipment applications.

### BACKGROUND OF THE INVENTION

Timing edge placement is often a critical parameter for high performance semiconductor testers. Having the ability to place the rising and/or falling edge of a test signal within a few picoseconds of a desired point in time may mean the difference in passing or failing large numbers of semiconductor devices under test.

Conventional timing generators that produce high accuracy timing signals are often employed in CMOS integrated circuits. CMOS technology provides relatively good performance at very low cost. However, CMOS ICs are often susceptible to temperature and other conditions that affect the performance of the circuit. To counter this, many CMOS timing generators employ sophisticated compensation techniques to minimize changes in delay.

With reference to FIG. 1, a conventional CMOS timing generator 10 that provides for temperature compensation typically includes a plurality of delay elements D1-DN coupled together to form a delay line. Each of the delay element outputs serve as timing selection inputs to a timing signaltselector (not shown). The same outputs are also used for a delay compensation scheme. A compensation multiplexer 12 is employed, that receives the delay outputs, and provides an output to a phase detector 14, where it is compared to a reference signal Vref to determine any phase difference. A compensation voltage is then generated in response to the magnitude of any phase difference, and fed to a charge pump or voltage-to-current converter 16.

The current generated by the converter is provided as bias current to the delay elements to control the delay.

FIG. 2 illustrates the conventional compensation multiplexer 12 in further detail. The multiplexer includes a plurality of input circuits 18 that tie in to a common output OUT_{P}, OUT_{N}. Each input circuit includes a pair of n-channel transistors, QINₐ and QIN_{b}. A current source transistor Q_{SOURCE} responsive to a control input signal I_{BIAS} is coupled to the QIN transistors to define a differential pair configuration.

Generally, in operation, the multiplexer activates one of the current source transistors (in response to a control input to the multiplexer) to turn on, depending on the delay element output desired at the multiplexer output. The activated current source draws current through the input transistors QIN_{P} and QIN_{N}, creating a current signal on the output OUT_{P}, OUT_{N}. The phase of the current signal on the output matches that fed to the input.

While this configuration works well for its intended applications, the delay associated with the multiplexer circuitry is often undersirable for high performance uses due to parasitic effects between the input transistors and the output. What is needed and currently unavailable is a multiplexer circuit for use in a timing generator that causes minimal delay. The multiplexer circuit of the present invention satisfies this need.

### SUMMARY OF THE INVENTION

The multiplexer circuit of the present invention provides a low-delay solution for the selection of timing signals in a CMOS-based timing generator. By minimizing the delay attributable to the multiplexer, the accuracy and performance of the timing generator is substantially improved.

To realize the foregoing advantages, the invention in one form comprises a timing generator for use in a semiconductor tester. The timing generator includes a delay line having a plurality of delay elements with respective phase-shifted outputs and a multiplexer. The multiplexer includes a plurality of inputs for receiving the phase shifted outputs, and an output. The multiplexer further includes a plurality of switch circuits corresponding to the input circuits and disposed between each input circuit and the output to selectively isolate each input circuit from the output. The timing generator also includes phase detection circuitry for detecting the phase shift between the multiplexer output and a reference signal.

In another form, the invention comprises a CMOS multiplexer for use in a semiconductor tester timing generator. The multiplexer includes an output, a plurality of input circuits, and a plurality of switch circuits. The switch circuits correspond to the input circuits and are disposed between each input circuit and the output to selectively isolate each input circuit from the output.

In a further form, the invention comprises a method of selecting a single timing signal from a plurality of timing signals for presentation at an output. The method comprises the steps of providing the plurality of timing signals at a plurality of input circuits; isolating the plurality of input circuits from the output with a plurality of switching circuits; and activating one of the plurality of input circuits while simultaneously switching a corresponding one of the plurality of switching circuits to couple the activated input circuit to the output.

Other features and advantages of the present invention will be apparent from the following detailed description when read in conjunction with the accompanying drawings.

### BRIEF DESCRIPTION OF THE DRAWINGS

The invention will be better understood by reference to the following more detailed description and accompanying drawings in which

FIG. 1 is a high-level block diagram of a conventional timing generator;

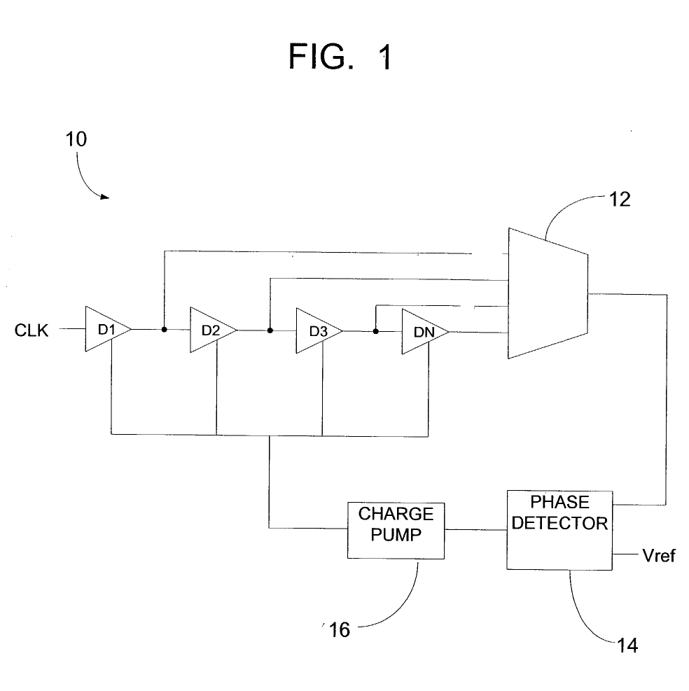

FIG. 2 is a partial schematic view of the conventional multiplexer circuitry employed in the timing generator of FIG. 1;

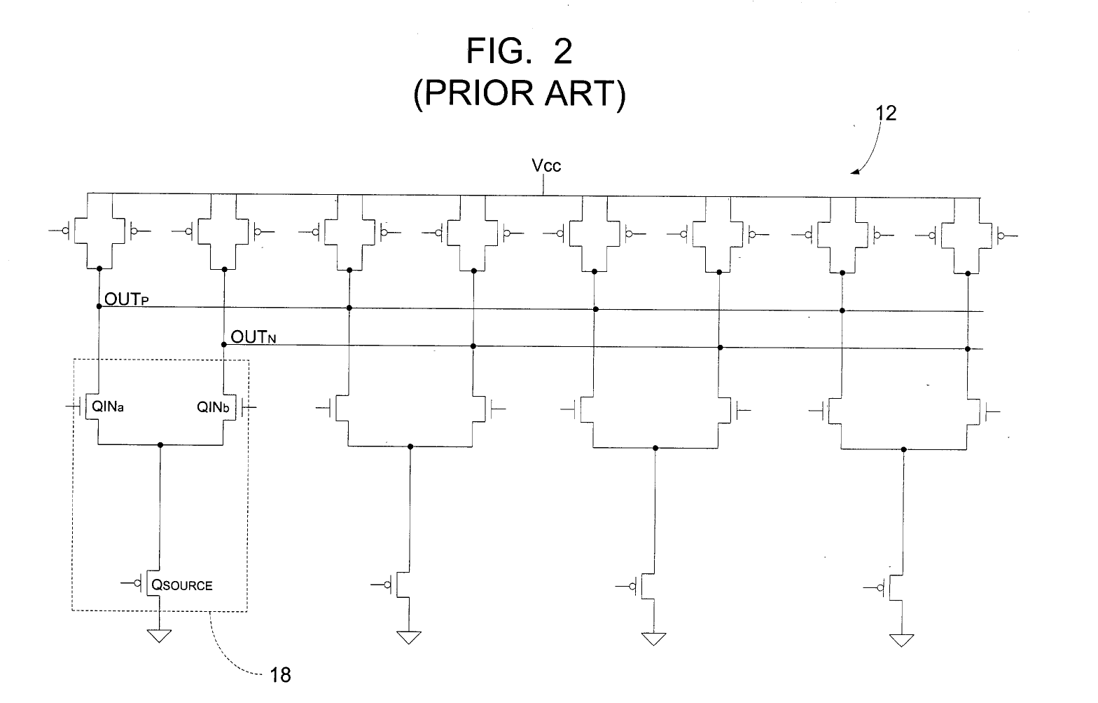

FIG. 3 is a high level block diagram of a timing generator according to one form of the present invention; and

FIG. 4 is a schematic illustration of one of the multiplexers shown in FIG. 3.

### DETAILED DESCRIPTION OF THE INVENTION

The multiplexer circuit of the present invention provides a low delay solution for high performance CMOS timing generators. This is accomplished by employing isolation switches that minimize parasitic effects acting on the multiplexer output. By minimizing parasitics on the multiplexer output, delay is also minimized.

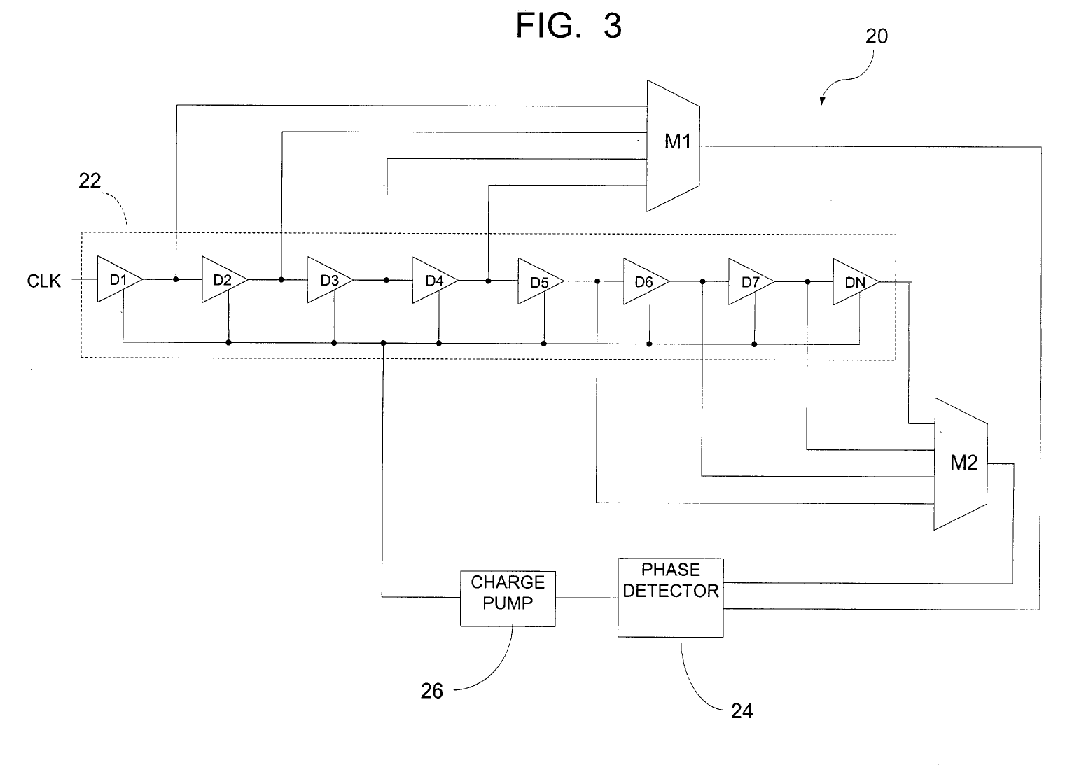

Referring now to FIG. 3, a timing generator according to one form of the present invention, generally designated 20, is shown for use with automatic test equipment. The timing generator is of the type that provides bias current compensation to control delay. The generator includes a delay line 22 comprising a set of N delay elements D1-DN, each providing a 1/N phase offset with respect to an input clock CLK. The delay line is split into groups, such that the delay element outputs from one group are fed to a first multiplexer M1, and the delay element outputs from a second group are fed to a second multiplexer M2. The multiplexer outputs, in turn, are coupled to a phase detector 24 for determining the phase difference between the two inputs. A voltage-to-current converter 26 receives a difference signal from the phase detector to generate bias current for the delay elements proportional to the phase difference. The change in bias current serves to control the delay through each element to a desired level.

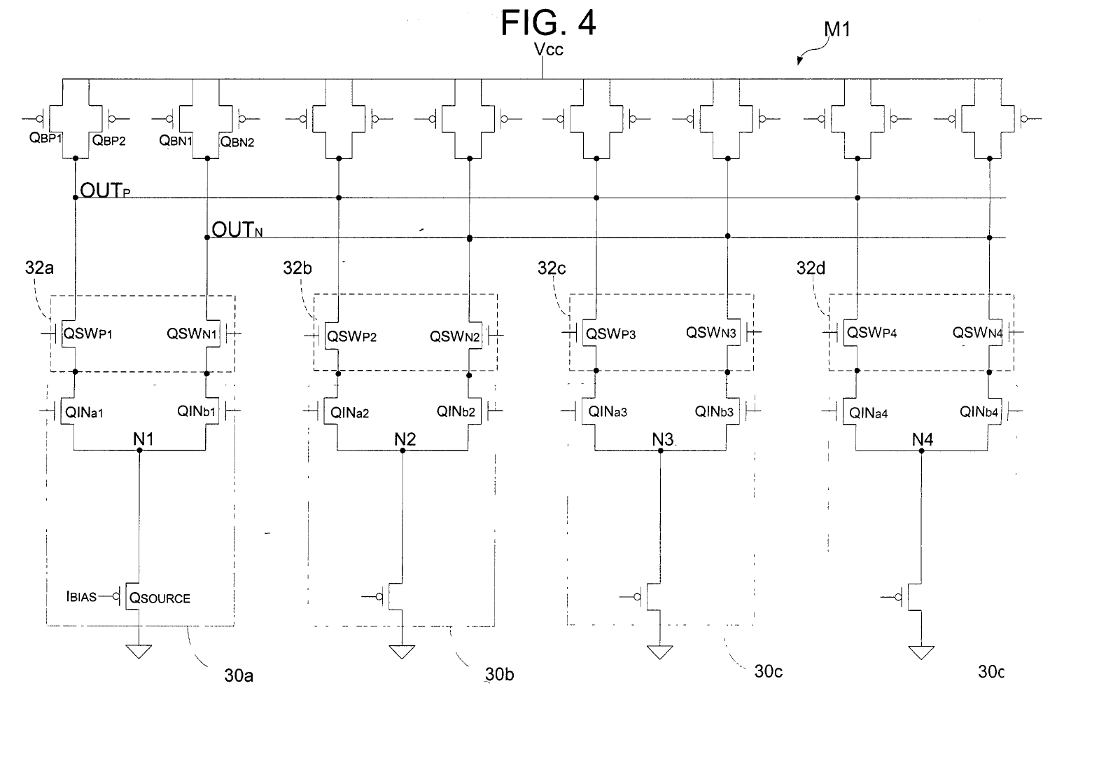

Referring now to FIG. 4, each multiplexer M1, M2 (only one multiplexer shown for clarity) employs a plurality of input circuits 30a-30d coupled to a common output OUT_{N}, OUT_{P}. In a preferred embodiment, each input circuit includes a pair of n-channel transistors Q_{INa} and Q_{INb} having a common source connection at node N1. The node also couples to a current source transistor Q_{SOURCE} responsive to a control input signal I_{BIAS}. Biasing transistor pairs Q_{BP1}, Q_{BP2} and Q_{BN1}, Q_{BN2} are disposed between the positive voltage rail Vcc and the output OUT_{N}, OUT_{P} to provide a stable bias voltage.

At this point, the construction of the multiplexer M1 is fairly conventional. However, the inventor has unexpectedly discovered that by isolating the input transistors Q_{INa} and Q_{INb} from the output OUT_{N}, OUT_{P}, when unselected, parasitic effects on the signal selected for transmission on the multiplexer output are substantially minimized. This is because, in the conventional multiplexer scheme, one differential pair is selected at a time by turning on the bias current source QSOURCE. The unselected pairs will have the current source turned off. However, the unselected pairs still receive input signals with high or low logic values on the gates of the QINa and QINb transistors. At the same time, the drains of the unselected pairs are connected at the active outputs OUTP and OUTN, which also toggle between high and low logic levels. Thus, the drains and gates of the unselected differential pair transistors receive signals that can be either at high or low logic values. For the cases when the drain is at logic low, and the gate is at logic high, the transistor opens due to reversing the drain and source effect. Current flows in this case and charges the drain capacitance of the QSOURCE transistor, even if this one is turned OFF. This current is supplied from the outputs OUTP and OUTN, thus increasing the overall propagation delay of the multiplexer.

The effect described above is eliminated in the present invention by inserting switching transistors QSWP and QSWN between the drains of QINP and QINN, and the outputs OUTP and OUTN. The unselected pairs will have the switch transistors turned OFF, thus blocking any current that tries to flow through the unselected differential pair transistors.

Further referring to FIG. 4, and as noted above, isolating the input circuit transistors Q_{INa} and Q_{INb} from the output OUT_{N}, OUT_{P} is accomplished by implementing switching circuits 32a-32d, in the form of additional transistors Q_{SWP} and Q_{SWN}, serially between each input transistor and the output. The switches are activated simultaneously with the control input I_{BIAS} to the current source Q_{SOURCE}.

In operation, the timing generator multiplexers M1 and M2 are programmed to select from one of the delay element output signals for routing to the phase detector 24 (FIG. 3). At the multiplexer level, the selected input circuit 30 (FIG. 4) responds to the activation command signal I_{BIAS} at the current source input, and simultaneously on the switches Q_{SWP} and Q_{SWN}. The input p and n channel transistors Q_{INP} and Q_{INN} then pass the input signal through to the output OUT_{N}, OUT_{P}. The unselected input circuits, on the other hand, remain in a passive mode with the respective p and n channel transistors isolated from the output by the inactive switches Q_{SWP2}, Q_{SWP3}, Q_{SWP4} and Q_{SWN2}, Q_{SWN3}, Q_{SWN4}.

Those skilled in the art will recognize the many benefits and advantages afforded by the present invention. Of significant importance is the implementation of the switch circuitry 32 to isolate unactivated input circuits 30 from the output OUT_{N}, OUT_{P}. As a result, no capacitive “stubs” are formed by the inactive input circuits. The reduction in capacitance substantially improves the multiplexer performance.

What is claimed is:

1. A CMOS multiplexer for use in a semiconductor tester timing generator, the multiplexer including:
an output;
a plurality of input circuits; and
a plurality of switch circuits corresponding to the input circuits and. disposed between each input circuit and the output to selectively isolate each input circuit from the output.

2. A CMOS multiplexer according to claim 1 wherein each of the plurality of switch circuits is disposed in series between each input circuit and the output.

3. A CMOS multiplexer according to claim 1 wherein each input circuit comprises:
an n-channel transistor;
a p-channel transistor coupled to the n-channel transistor;
a current source tied to both the n-channel and p-channel transistors; and
wherein each switch circuit includes a first switch disposed in series between the output and the n-channel transistor, and a second switch disposed in series between the output and the p-channel transistor.

4. A timing generator for use in a semiconductor tester, the timing generator including:
a delay line having a plurality of delay elements with respective phase-shifted outputs;
a multiplexer having a plurality of inputs for receiving the phase shifted outputs, and an output, the multiplexer further including a plurality of switch circuits corresponding to the input circuits and disposed between each input circuit and the output to selectively isolate each input circuit from the output; and
phase detection circuitry for detecting the phase shift between the multiplexer output and a reference signal.

5. A CMOS multiplexer according to claim 4 wherein each of the plurality of switch circuits is disposed in series between each input circuit and the output.

6. A CMOS multiplexer according to claim 4 wherein each input circuit comprises:
an n-channel transistor;
a p-channel transistor coupled to the n-channel transistor;
a current source tied to both the n-channel and p-channel transistors; and
wherein each switch circuit includes a first switch disposed in series between the output and the n-channel transistor, and a second switch disposed in series between the output and the p-channel transistor.

7. A method of selecting a single timing signal from a plurality of timing signals for presentation at an output, the method comprising the steps:
providing the plurality of timing signals at a plurality of input circuits;
isolating the plurality of input circuits from the output with a plurality of switching circuits; and
activating one of the plurality of input circuits while simultaneously switching a corresponding one of the plurality of switching circuits to couple the activated input circuit to the output.
